(19) United States
(12) Patent Application Publication
(10) Pub. No.: US 2024/0186382 A1
(43) Pub. Date: Jun. 6, 2024

(54) NITRIDE SEMICONDUCTOR DEVICE AND MANUFACTURING METHOD THEREOF

(71) Applicant: ROHM CO., LTD., Kyoto-shi (JP)

(72) Inventor: Isamu NISHIMURA, Kyoto-shi (JP)

(73) Assignee: ROHM CO., LTD., Kyoto-shi (JP)

(21) Appl. No.: 18/522,420

(22) Filed: Nov. 29, 2023

(30) Foreign Application Priority Data
Dec. 1, 2022 (JP) 2022-192909

(51) Int. Cl. H01L 29/20; H01L 21/02; H01L 29/08; H01L 29/40; H01L 29/78

(52) U.S. Cl. CPC H01L 29/2003; H01L 21/0254; H01L 29/0891; H01L 29/407; H01L 29/7833

(57) ABSTRACT

The present disclosure provides a nitride semiconductor device. The nitride semiconductor device includes a gate layer formed on an electron supply layer; a first insulating film, formed on the gate layer and having an opening exposing the gate layer; and a gate electrode including a gate field plate portion formed on the first insulating film. A side surface of the first insulating film is located further inside the gate electrode than a side surface of the gate field plate portion. The nitride semiconductor device further includes a second insulating film covering at least side surfaces of each of the gate layer, the first insulating film and the gate electrode. The second insulating film includes a portion embedded in a recessed portion formed by a lower surface of the gate field plate portion, the side surface of the first insulating film and an upper surface of the gate layer.

### CROSS-REFERENCE TO RELATED APPLICATION

This application is based upon and claims the benefit of priority from Japanese Patent Application No. 2022-192909, filed on Dec. 1, 2022, the entire contents of which are incorporated herein by reference.

### TECHNICAL FIELD

The disclosure relates to a nitride semiconductor device and a method for manufacturing the same.

### BACKGROUND

Currently, the commercialization of high electron mobility transistors (HEMT) using group III nitride semiconductors such as gallium nitride (GaN) (hereinafter sometimes referred to as “nitride semiconductors” for short) is progressing. Patent document 1 discloses an example of a normally-off HEMT using a nitride semiconductor.

The nitride semiconductor device described in Patent document 1 includes: an electron traveling layer; an electron supply layer provided on the electron traveling layer; and a gate layer provided on the electron supply layer and made of a nitride semiconductor containing an acceptor type impurity. A gate electrode is provided on the gate layer. In this structure, two-dimensional electron gas (2DEG) is generated in the electron traveling layer near the heterojunction interface between the electron traveling layer and the electron supply layer as a current path (channel) between the source electrode and the drain electrode. Furthermore, when the gate electrode is not biased and under a zero bias voltage, the channel in the electron traveling layer in the region directly below the gate electrode disappears, thereby realizing a normally off state.

### PRIOR ART DOCUMENT

### Patent Publication

[Patent document 1] Japan Patent Publication No. 2017-073506A

### BRIEF DESCRIPTION OF THE DRAWINGS

FIG. 1 is a schematic cross-sectional view of an exemplary nitride semiconductor device according to one embodiment.

FIG. 2 is an exemplary schematic top view of the nitride semiconductor device of FIG. 1.

FIG. 3 is an enlarged cross-sectional view of the gate layer, the gate electrode, and their surroundings of the nitride semiconductor device of FIG. 1.

FIG. 4 is an enlarged cross-sectional view of a part of the gate layer, a part of the gate electrode, and their surroundings of the nitride semiconductor device of FIG. 3.

FIG. 5 is a schematic cross-sectional view showing exemplary manufacturing steps of the nitride semiconductor device of FIG. 1.

FIG. 6 is a schematic cross-sectional view showing exemplary manufacturing steps subsequent to FIG. 5.

FIG. 7 is a schematic cross-sectional view showing exemplary manufacturing steps subsequent to FIG. 6.

FIG. 8 is a schematic cross-sectional view showing exemplary manufacturing steps subsequent to FIG. 7.

FIG. 9 is a schematic cross-sectional view showing exemplary manufacturing steps subsequent to FIG. 8.

FIG. 10 is a schematic cross-sectional view showing exemplary manufacturing steps subsequent to FIG. 9.

FIG. 11 is a schematic cross-sectional view showing exemplary manufacturing steps subsequent to FIG. 10.

FIG. 12 is a schematic cross-sectional view showing exemplary manufacturing steps subsequent to FIG. 11.

FIG. 13 is a schematic cross-sectional view showing exemplary manufacturing steps subsequent to FIG. 12.

FIG. 14 is a schematic cross-sectional view showing exemplary manufacturing steps subsequent to FIG. 13.

FIG. 15 is a schematic cross-sectional view of a nitride semiconductor device according to a comparative example.

FIG. 16 is an enlarged cross-sectional view of a part of the gate layer, a part of the gate electrode, and their surroundings of the nitride semiconductor device according to one modified example.

FIG. 17 is an enlarged cross-sectional view of a part of the gate layer, a part of the gate electrode, and their surroundings in the nitride semiconductor device according to one modified example.

FIG. 18 is an enlarged cross-sectional view of a part of the gate layer, a part of the gate electrode, and their surroundings in the nitride semiconductor device according to one modified example.

### DETAILED DESCRIPTION OF THE EMBODIMENTS

Hereinafter, several embodiments of the nitride semiconductor device and the method for manufacturing the nitride semiconductor device of the present disclosure will be described with reference to the accompanying drawings. In addition, for the sake of simple and clear explanation, the components shown in the drawings are not drawn on a fixed scale. In order to facilitate understanding, hatching may be omitted in cross-sectional views. The accompanying drawings merely illustrate implementations of the disclosure and should not be construed as limiting the disclosure.

The following detailed description includes devices, systems, and methods that embody exemplary implementations of the present disclosure. The detailed description is intended to be illustrative only and is not intended to limit the embodiments of the present disclosure or the application and uses of such embodiments.

### Cross-Sectional Structure of Nitride Semiconductor Device

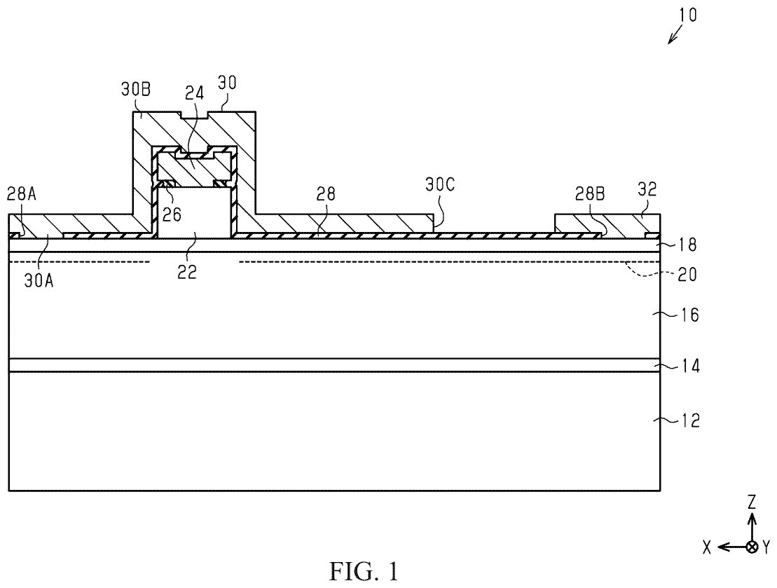

FIG. 1 is a schematic cross-sectional view of an exemplary nitride semiconductor device 10 according to one embodiment. The nitride semiconductor device 10 may include a substrate 12, a buffer layer 14 formed on the substrate 12, and an electron traveling layer 16 formed on the buffer layer 14. The Z-axis direction of the mutually orthogonal XYZ axes shown in FIG. 1 is a direction orthogonal to the surface of the substrate 12. In addition, terms such as “top view” used in this specification mean that the nitride semiconductor device 10 is viewed from above along the Z-axis direction unless otherwise specified.

The substrate 12 may be formed of silicon (Si), silicon carbide (SiC), gallium nitride (GaN), sapphire, or other substrate materials. The substrate 12 may be a semiconductor substrate. In one example, the substrate 12 may be a Si substrate. The thickness of the substrate 12 is, for example, between about 200 μm and about 1500 μm.

The buffer layer 14 may include one or more nitride semiconductor layers. The buffer layer 14 can be made of, for example, any material capable of suppressing the generation of warpage of the substrate 12 and cracks in the nitride semiconductor device 10 due to the thermal expansion coefficient mismatch between the substrate 12 and the electron traveling layer 16. For example, the buffer layer 14 can include at least one of an aluminum nitride (AlN) layer, an aluminum gallium nitride (AlGaN) layer and a graded AlGaN layer having different aluminum (Al) compositions. For example, the buffer layer 14 may be made of a single AlN layer, a single AlGaN layer, a layer having an AlGaN/GaN superlattice structure, a layer having an AlN/AlGaN superlattice structure, or a layer having an AlN/GaN superlattice structure.

In one example, the buffer layer 14 may include an AlN layer, i.e. a first buffer layer, formed on the substrate 12 and an AlGaN layer, i.e. a second buffer layer, formed on the AlN layer (the first buffer layer). The first buffer layer may be, for example, an AlN layer having a thickness between 100 nm and 300 nm. On the other hand, the second buffer layer may be formed by laminating multiple times of graded AlGaN having a thickness between 100 nm and 300 nm, for example. Further, in order to suppress the leakage current in the buffer layer 14, impurities may be introduced into a part of the buffer layer 14 to make the buffer layer 14 semi-insulating. Under such circumstance, the impurity is, for example, carbon (C) or iron (Fe), and the impurity concentration may be, for example, 4×10¹⁶ cm⁻³ or more.

The electron traveling layer 16 is made of a nitride semiconductor. The electron traveling layer 16 may be a GaN layer, for example. The electron traveling layer 16 has a thickness between, for example, between about 0.5 μm and about 2 μm. Further, in order to suppress the leakage current in the electron traveling layer 16, impurities may be introduced into a part of the electron traveling layer 16 to make the electron traveling layer 16 semi-insulating except for the surface layer region. In this case, the impurity is, for example, C, and the peak concentration of the impurity in the electron traveling layer 16 may be, for example, 1×10¹⁹ cm⁻³ or more.

The nitride semiconductor device 10 includes an electron supply layer 18 made of a nitride semiconductor. The electron supply layer 18 is formed on the electron traveling layer 16. The electron supply layer 18 is made of a nitride semiconductor having a larger band gap than the electron traveling layer 16, and may be an AlGaN layer, for example. Under such circumstance, since the more the Al composition is, the larger the band gap is, the AlGaN layer, i.e. the electron supply layer 18, has a larger band gap than the GaN layer, which is the electron traveling layer 16. In one example, the electron supply layer 18 is made of AlₓGa₁₋ₓN, and x is 0.1<x<0.4, more preferably 0.1<x<0.3. The electron supply layer 18 may have a thickness between about 5 nm and about 20 nm. In one example, the electron supply layer 18 may have a thickness of 8 nm or more.

The electron traveling layer 16 and the electron supply layer 18 are made of nitride semiconductors having different lattice constants. Therefore, the nitride semiconductor (for example, GaN) constituting the electron traveling layer 16 and the nitride semiconductor (for example, AlGaN) constituting the electron supply layer 18 form a heterojunction of a lattice mismatch system. Through the spontaneous polarization of the electron traveling layer 16 and the electron supply layer 18 and the piezoelectric polarization caused by the stress on the electron supply layer 18 near the heterojunction interface, the energy level of the conduction band of the electron traveling layer 16 near the heterojunction interface is lower than the Fermi level. Thereby, the two-dimensional electron gas (2DEG) 20 diffuses into the electron traveling layer 16 at a position close to the heterojunction interface between the electron traveling layer 16 and the electron supply layer 18 (for example, within a range of about several nm from the interface).

The nitride semiconductor device 10 further includes a gate layer 22 formed on the electron supply layer 18, a first insulating film 26 formed on the gate layer 22, and a gate electrode 24 formed on the first insulating film 26.

The gate layer 22 may be formed on a portion of the electron supply layer 18. The gate layer 22 is made of a nitride semiconductor containing acceptor-type impurities. The gate layer 22 may be made of any material with a smaller band gap than the electron supply layer 18 (e.g., an AlGaN layer). In one example, the gate layer 22 may be a GaN (p-type GaN) layer containing acceptor-type impurities. The acceptor-type impurity may include at least one of zinc (Zn), magnesium (Mg) and C. The peak concentration of the acceptor-type impurity in the gate layer 22 may be set to be between about 7×10¹⁸ cm⁻³ and about 1×10²⁰ cm⁻³. In one example, the gate layer 22 may be a GaN layer containing at least one of Mg and Zn as an impurity.

The gate electrode 24 is located above the electron supply layer 18. The gate electrode 24 may be made of one or more metal layers. In one example, the gate electrode 24 may be made of a titanium nitride (TiN) layer. In another example, the gate electrode 24 may be made of a first metal layer formed of titanium (Ti) and a second metal layer formed of TiN and provided on the first metal layer. The gate electrode 24 can form a Schottky junction with the gate layer 22. In addition, detailed descriptions of the structures such as the cross-sectional shape of the gate layer 22 and the gate electrode 24 will be described later.

The first insulating film 26 may be formed on a part of the gate layer 22. The first insulating film 26 can be sandwiched between the gate layer 22 and the gate electrode 24. The first insulating film 26 may be formed of at least one of silicon nitride (SiN), silicon dioxide (SiO₂), silicon oxynitride (SiON), aluminum oxide (Al₂O₃), AlN and aluminum oxynitride (AlON). In one example, the first insulating film 26 may be formed of Si₃N₄.

The nitride semiconductor device 10 further includes a second insulating film 28 covering the electron supply layer 18, the gate layer 22, the first insulating film 26 and the gate electrode 24. The second insulating film 28 includes a first opening 28A and a second opening 28B that expose the surface of the electron supply layer 18. The first opening 28A and the second opening 28B can be spaced apart in a specified direction (the X-axis direction in FIG. 1). The gate layer 22 is located between the first opening 28A and the second opening 28B of the second insulating film 28 and is spaced apart from each of the first opening 28A and the second opening 28B. In other words, the first opening 28A and the second opening 28B are arranged on both sides of the gate layer 22 in a specified direction (the X-axis direction in FIG. 1). More specifically, the gate layer 22 is located closer to the first opening 28A than the second opening 28B.

The second insulating film 28 is, for example, a passivation film, and may be formed of at least one of SiN, SiO₂, SiON, Al₂O₃, AlN and AlON. In one example, the second insulating film 28 may be formed of Si₃N₄. That is, the first insulating film 26 and the second insulating film 28 may be formed of the same material. The second insulating film 28 may have a thickness between about 80 nm and about 200 nm, for example. The detailed structures of the first insulating film 26 and the second insulating film 28 will be described later.

The nitride semiconductor device 10 further includes a source electrode 30 connected to the electron supply layer 18 via the first opening 28A, and a drain electrode 32 connected to the electron supply layer 18 via the second opening 28B. It can be said that the source electrode 30 and the drain electrode 32 are arranged on both sides of the gate layer 22 in a predetermined direction (the X-axis direction in FIG. 1). The source electrode 30 and the drain electrode 32 may be made of one or more metal layers (for example, any combination of a Ti layer, a TiN layer, an Al layer, an AlSiCu layer, an AlCu layer, etc.).

The source electrode 30 is filled in the first opening 28A, and is in ohmic contact with the 2DEG 20 directly under the electron supply layer 18 through the first opening 28A. In one example, the source electrode 30 may include a source contact portion 30A filled in the first opening 28A, and a source field plate portion 30B covering the second insulating film 28. The source field plate portion 30B is continuous with the source contact portion 30A and is integrally formed with the source contact portion 30A. The source field plate portion 30B includes an end portion 30C located between the second opening 28B and the gate layer 22 in a top view. When a drain voltage is applied to the drain electrode 32 in a zero-bias state in which a gate voltage is not applied to the gate electrode 24, the source field plate portion 30B exerts a relaxation function on the electric field concentration near an end of the gate electrode 24 and near an end of the gate layer 22.

The drain electrode 32 is spaced apart from the source field plate portion 30B in the X-axis direction. The drain electrode 32 is filled in the second opening 28B, and is in ohmic contact with the 2DEG 20 directly below the electron supply layer 18 via the second opening 28B.

### Planar Structure of Nitride Semiconductor Device

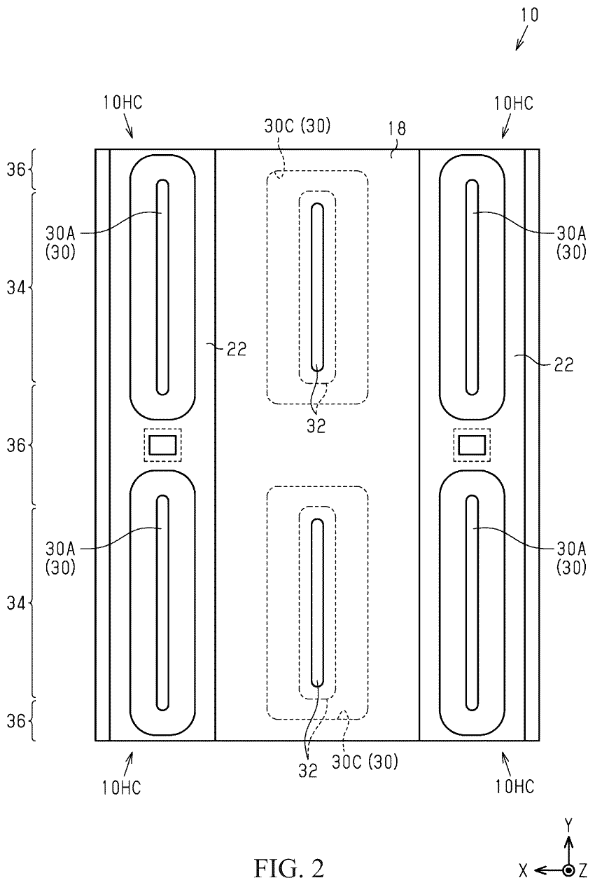

FIG. 2 is a schematic partial enlarged top view of the nitride semiconductor device 10 of FIG. 1. In order to simplify the illustration and make it easier to understand the drawing, the gate electrode 24, the second insulating film 28, and the source field plate portion 30B of the source electrode 30 are not shown in FIG. 2. On the other hand, the end portion 30C of the source field plate portion 30B is drawn with a two-dot chain line. In addition, a portion of the drain electrode 32 that is in contact with the electron supply layer 18 is drawn with a solid line, while a portion provided on the second insulating film 28 is drawn with a two-dot chain line.

As shown in FIG. 2, the nitride semiconductor device 10 includes an active region 34 that contributes to transistor operation and an inactive region 36 that does not contribute to transistor operation. In the example of FIG. 2, the active regions 34 and inactive regions 36 are alternately arranged along the Y-axis direction. The drain electrode 32 is formed in the active region 34. In one example, the active region 34 may extend in substantially the same range as the drain electrode 32 in the Y-axis direction. The inactive region 36 may extend in a range in the Y-axis direction where the drain electrode 32 does not exist. Therefore, the inactive region 36 and the active region 34 are adjacent to each other in the Y-axis direction.

In the active region 34, the source electrode 30, the gate layer 22 in which the gate electrode 24 (referring to FIG. 1) is located, and the drain electrode 32 are arranged adjacent to each other in the X-axis direction on the electron supply layer 18. The combination of the source electrode 30, the gate layer 22 (the gate electrode 24), and the drain electrode 32 adjacent in the X-axis direction constitutes one HEMT unit 10HC. In the example of FIG. 2, four HEMT units 10HC are arranged along the X-axis direction in each active region 34. In addition, more HEMT units 10HC can actually be arranged in each active region 34.

### Detailed Structure of the Gate Electrode and its Surroundings

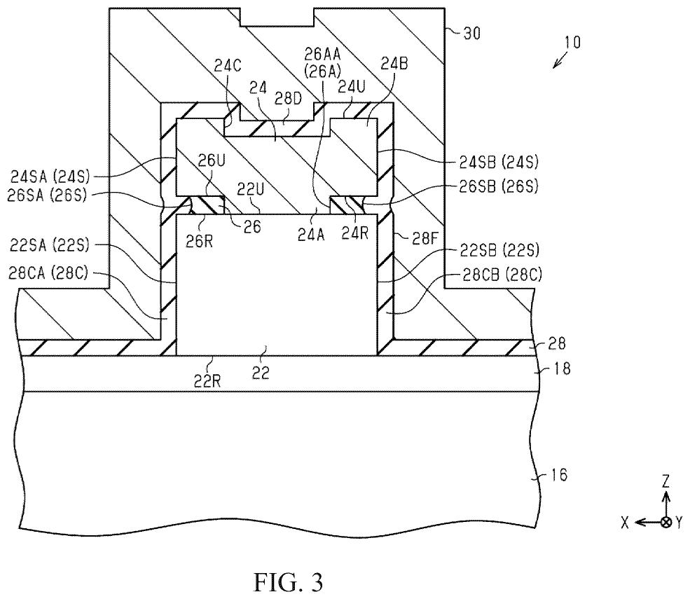

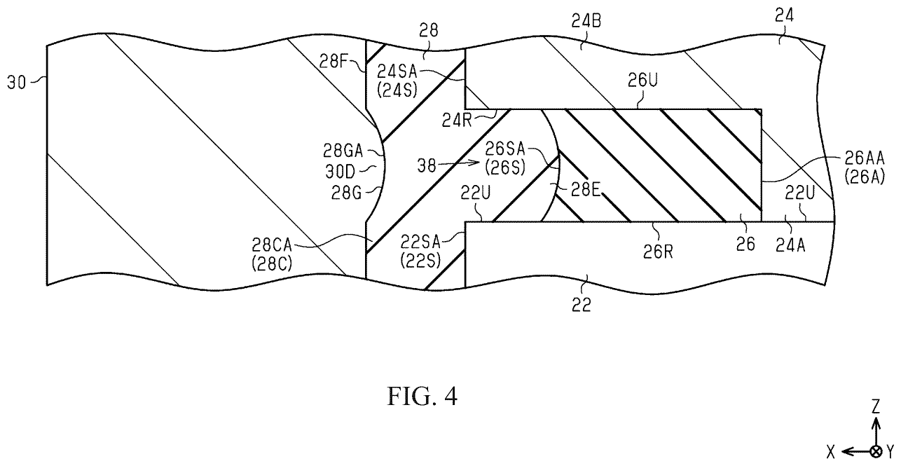

FIG. 3 is a schematic partial enlarged cross-sectional view of the gate layer 22, the gate electrode 24, the first insulating film 26, the second insulating film 28, and their surroundings. FIG. 4 is a schematic partial enlarged cross-sectional view of a portion of the first insulating film 26 near the source electrode 30 and its surroundings in FIG. 3.

As shown in FIG. 3, the gate layer 22 has a ridge-shaped cross-sectional shape. The gate layer 22 includes a lower surface 22R in contact with the electron supply layer 18, an upper surface 22U facing the opposite side to the lower surface 22R, and a side surface 22S connecting the lower surface 22R and the upper surface 22U. The side surface 22S is a surface intersecting both the upper surface 22U and the lower surface 22R. In the example shown in FIG. 3, the side surface 22S extends in the Z-axis direction. That is, it can be said that the side surface 22S is a surface orthogonal to both the upper surface 22U and the lower surface 22R. In the example of FIG. 3, the side surface 22S includes a side surface 22SA provided near the source electrode 30 (referring to FIG. 1) and a side surface 22SB provided near the drain electrode 32 (referring to FIG. 1).

The first insulating film 26 is in contact with the upper surface 22U of the gate layer 22. The film thickness of the first insulating film 26 is thinner than the thickness of the gate layer 22. In addition, the film thickness of the first insulating film 26 is thinner than the thickness of the gate electrode 24. In one example, the film thickness of the first insulating film 26 is between about 50 nm and about 100 nm.

The first insulating film 26 includes a lower surface 26R in contact with the upper surface 22U of the gate layer 22, an upper surface 26U facing the opposite side to the lower surface 26R, and a side surface 26S connecting the lower surface 26R and the upper surface 26U. The side surface 26S is a surface that intersects both the upper surface 26U and the lower surface 26R. In the example of FIG. 3, the side surface 26S includes a side surface 26SA provided on the side near the source electrode 30 and a side surface 26SB provided on the side near the drain electrode 32.

The first insulating film 26 includes an opening 26A that exposes the upper surface 22U of the gate layer 22. The opening 26A exposes the central portion in the X-axis direction of the upper surface 22U of the gate layer 22. The first insulating film 26 includes an inner side surface 26AA forming the opening 26A. In the example of FIG. 3, the inner side surface 26AA extends in the Z-axis direction.

The gate electrode 24 is in contact with both the upper surface 22U of the gate layer 22 and the upper surface 26U of the first insulating film 26. The gate electrode 24 includes a gate contact portion 24A that is in contact with the gate layer 22 via the opening 26A of the first insulating film 26, and a gate field plate portion 24B formed on the first insulating film 26. The gate field plate portion 24B is continuous with the gate contact portion 24A and is formed integrally with the gate contact portion 24A.

The gate contact portion 24A fills the opening 26A of the first insulating film 26 and is in contact with the upper surface 22U of the gate layer 22. The gate contact portion 24A is in contact with inner side surface 26AA of first insulating film 26.

The gate field plate portion 24B is in contact with the upper surface 26U of the first insulating film 26. The gate field plate portion 24B extends toward both sides in the X-axis direction with respect to the gate contact portion 24A.

The gate electrode 24 includes a lower surface 24R in contact with the upper surface 26U of the first insulating film 26, an upper surface 24U facing the opposite side to the lower surface 24R, and a side surface 24S connecting the lower surface 24R and the upper surface 24U. The side surface 24S is a surface that intersects both the upper surface 24U and the lower surface 24R. Here, the side surface 24S means the side surface of the gate field plate portion 24B. In the example of FIG. 3, the side surface 24S is a surface orthogonal to both the upper surface 24U and the lower surface 24R.

In the example of FIG. 3, the side surface 24S includes a side surface 24SA provided on the side near the source electrode 30 and a side surface 24SB provided on the side near the drain electrode 32. The side surface 24S of the gate electrode 24 and the side surface 26S of the first insulating film 26 face the same side. More specifically, the side surface 24SA of the gate electrode 24 and the side surface 26SA of the first insulating film 26 face the same side, and the side surface 24SB of the gate electrode 24 and the side surface 26SB of the first insulating film 26 face the same side. Therefore, it can be said that the first insulating film 26 includes the side surfaces 26S (26SA, 26SB) facing the same direction as the side surfaces 24S (24SA, 24SB) of the gate electrode 24 (the gate field plate portion 24B).

In the example of FIG. 3, the side surface 24SA of the gate electrode 24 and the side surface 22SA of the gate layer 22 are located at the same position as each other in the X-axis direction, and the side surface 24SB of the gate electrode 24 and the side surface 22SB of the gate layer 22 are located at the same position as each other in the X-axis direction.

A recess 24C is formed at the upper end of the gate electrode 24. The recess 24C is recessed from the upper surface 24U of the gate electrode 24 toward the lower surface 24R. In top view, the recess 24C is provided at a position overlapping the gate contact portion 24A.

The second insulating film 28 covers at least the side surfaces 22SA and 22SB of the gate layer 22, the side surfaces 26SA and 26SB of the first insulating film 26, and the side surfaces 24SA and 24SB of the gate electrode 24. More specifically, the second insulating film 28 is in contact with each of the side surfaces 22SA and 22SB of the gate layer 22, the side surfaces 26SA and 26SB of the first insulating film 26, and the side surfaces 24SA and 24SB of the gate electrode 24. It can also be said that the second insulating film 28 extends over and fully contacts with each of the side surfaces 22SA and 22SB of the gate layer 22, the side surfaces 26SA and 26SB of the first insulating film 26, and the side surfaces 24SA and 24SB of the gate electrode 24. It can be said that the second insulating film 28 includes the side cover portion 28C covering the side surfaces 22SA and 22SB of the gate layer 22, the side surfaces 26SA and 26SB of the first insulating film 26, and the side surfaces 24SA and 24SB of the gate electrode 24. The side cover portion 28C includes a side cover portion 28CA that covers the side surface 22SA of the gate layer 22, the side furface 26SA of the first insulating film 26, and the side surface 24SA of the gate electrode 24, and a side cover portion 28CB that covers the side surface 22SB of the gate layer 22, the side surface 26SB of the first insulating film 26, and the side surface 24SB of the gate electrode 24.

In the example of FIG. 3, the second insulating film 28 covers the upper surface 24U of the gate electrode 24 and the recess 24C. The second insulating film 28 is in contact with each of the upper surface 24U of the gate electrode 24 and the recess 24C. It can be said that the second insulating film 28 includes the upper surface cover portion 28D that covers the upper surface 24U of the gate electrode 24 and the recess 24C. In the example of FIG. 3, the side cover portion 28C and the upper surface cover portion 28D are formed integrally.

As shown in FIG. 4, the side surface 26SA of the first insulating film 26 is curvedly recessed inward of the first insulating film 26 from the upper surface 26U and the lower surface 26R of the first insulating film 26 toward the center of the first insulating film 26 in the thickness direction. That is, the side surface 26SA is formed in a curved shape in the cross-sectional view of FIG. 4. In this way, the shape of the side surface 26SA of the first insulating film 26 is different from the shapes of the side surface 24SA of the gate electrode 24 and the side surface 22SA of the gate layer 22.

The side surface 26SA of the first insulating film 26 is located further inside the gate electrode 24 than the side surface 24SA of the gate electrode 24 (the gate field plate portion 24B). In addition, the side surface 26SA of the first insulating film 26 is located further inside the gate layer 22 than the side surface 22SA of the gate layer 22. Accordingly, the recessed portion 38 is formed by the lower surface 24R of the gate field plate portion 24B, the side surface 26SA of the first insulating film 26, and the upper surface 22U of the gate layer 22. Since the side surface 26SA of the first insulating film 26 is formed in a curved shape, and the side surface 26SA constitutes the bottom surface of the recessed portion 38, it can be said that the recessed portion 38 is formed in a curved shape.

In the example of FIG. 4, the depth of the recessed portion 38 is smaller than the film thickness of the first insulating film 26. Here, the depth of the recessed portion 38 can be determined by, for example, the distance in the X-axis direction between the side surface 24SA of the gate field plate portion 24B of the gate electrode 24 and the center of the side surface 26SA of the first insulating film 26 in the thickness direction of the first insulating film 26. In addition, the depth of the recessed portion 38 is smaller than the film thickness of the second insulating film 28.

The second insulating film 28 includes an embedded portion 28E, which is a portion embedded in the recessed portion 38. The embedded portion 28E is in contact with each of the lower surface 24R of the gate field plate portion 24B, the side surface 26SA of the first insulating film 26, and the upper surface 22U of the gate layer 22. Therefore, the front end surface of the embedded portion 28E is formed into a curved convex shape.

A recess 28G is formed in a portion of the outer surface 28F of the second insulating film 28 corresponding to the embedded portion 28E. That is, the outer surface 28F of the second insulating film 28 includes the recess 28G that is recessed by being embedded in the recessed portion 38. The recess 28G is formed in a curved shape in the cross-sectional view of FIG. 4. The depth of the recess 28G is equal to or less than the depth of the recessed portion 38.

The recess 28G is located, for example, outside the side surface 24SA of the gate electrode 24 (the gate field plate portion 24B). It can be said that the bottom surface 28GA of the recess 28G is located outside the side surface 24SA of the gate electrode 24, for example. In addition, the recess 28G is located, for example, outside the side surface 22SA of the gate layer 22. The bottom surface 28GA of the recess 28G is located, for example, outside the side surface 22SA of the gate layer 22.

In addition, although not shown in the figure, the shape of the side surface 26SB of the first insulating film 26 is curved similarly to the shape of the side surface 26SA. The side surface 26SB has a symmetrical shape that is symmetrical to the side surface 26SA with respect to an imaginary line facing the center of the first insulating film 26 in the X-axis direction along the Z-axis direction. In addition, the recessed portion 38 is also made of the side surface 26SB of the first insulating film 26, the side surface 24SB of the gate electrode 24, and the side surface 22SB of the gate layer 22. In addition, the second insulating film 28 includes an embedded portion 28E embedded in a recessed portion 38 formed by the side surface 26SB of the first insulating film 26, the side surface 24SB of the gate electrode 24, and the side surface 22SB of the gate layer 22. The second insulating film 28 includes a recess 28G corresponding to the embedded portion 28E.

The source field plate portion 30B of the source electrode 30 covering the second insulating film 28 includes an embedded portion 30D embedded in the recess 28G of the second insulating film 28. As the embedded portion 30D, the source field plate portion 30B includes an embedded portion embedded in the recess 28G of the second insulating film 28 close to the source electrode 30 and an embedded portion embedded in the recess 28G adjacent to the drain electrode 32.

### Method for Manufacturing Nitride Semiconductor Device

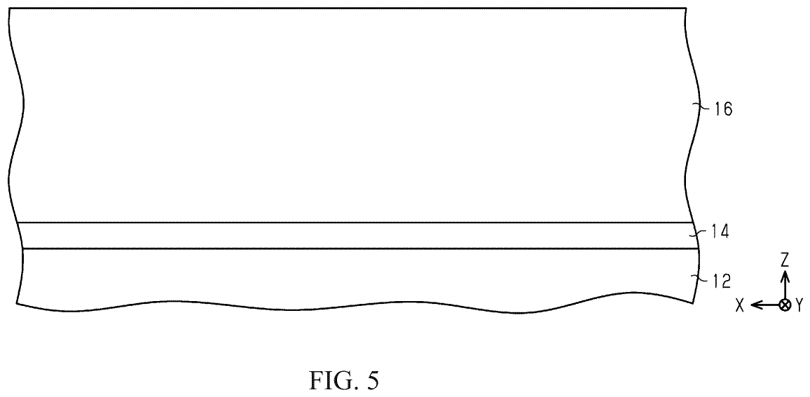

Next, an example of a method of manufacturing the nitride semiconductor device 10 shown in FIG. 1 will be described. FIGS. 5 to 14 are schematic cross-sectional views showing exemplary manufacturing steps of the nitride semiconductor device 10. Further, in order to facilitate understanding, in FIGS. 5 to 14, the same components as those in FIG. 1 are denoted by the same reference numerals.

The method for manufacturing the nitride semiconductor device 10 includes forming the electron traveling layer 16 made of the nitride semiconductor.

As shown in FIG. 5, for example, the buffer layer 14 may be formed on a Si substrate, that is, the substrate 12, and then the electron traveling layer 16 may be formed on the buffer layer 14. The buffer layer 14 and the electron traveling layer 16 may be epitaxially grown using the Metal Organic Chemical Vapor Deposition (MOCVD) method.

Although detailed illustration is omitted, in one example, the buffer layer 14 may be a multi-layer buffer layer. The multi-layer buffer layer may include an AlN layer (a first buffer layer) formed on the substrate 12 and a graded AlGaN layer (a second buffer layer) formed on the AlN layer. The graded AlGaN layer can be formed, for example, by stacking three AlGaN layers with Al compositions of 75%, 50%, and 25% in order from the side close to the AlN layer. The electron traveling layer 16 formed on the buffer layer 14 may be a GaN layer.

The method for manufacturing the nitride semiconductor device 10 includes forming the electron supply layer 18 made of the nitride semiconductor and forming the nitride semiconductor layer 40 on the electron supply layer 18.

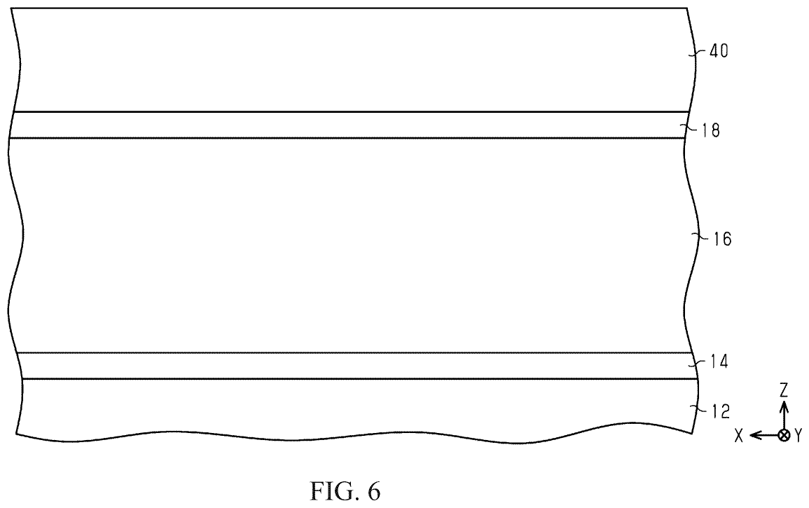

As shown in FIG. 6, the electron supply layer 18 may be formed on the electron traveling layer 16, and then the nitride semiconductor layer 40 may be formed on the electron supply layer 18. The electron supply layer 18 and the nitride semiconductor layer 40 may be epitaxially grown using the MOCVD method.

The electron traveling layer 16 may be a GaN layer, and the electron supply layer 18 may be an AlGaN layer. Therefore, the nitride semiconductor constituting the electron supply layer 18 has a larger band gap than the electron traveling layer 16.

The nitride semiconductor layer 40 may be made of a nitride semiconductor containing acceptor type impurities. In one example, the nitride semiconductor layer 40 containing acceptor-type impurities may be formed by doping Mg while growing the nitride semiconductor layer 40. The nitride semiconductor layer 40 may be formed of GaN, for example. Therefore, the nitride semiconductor layer 40 is made of the nitride semiconductor having a smaller band gap than the electron supply layer 18. The nitride semiconductor layer 40 is a semiconductor layer constituting the gate layer 22 (referring to FIG. 1).

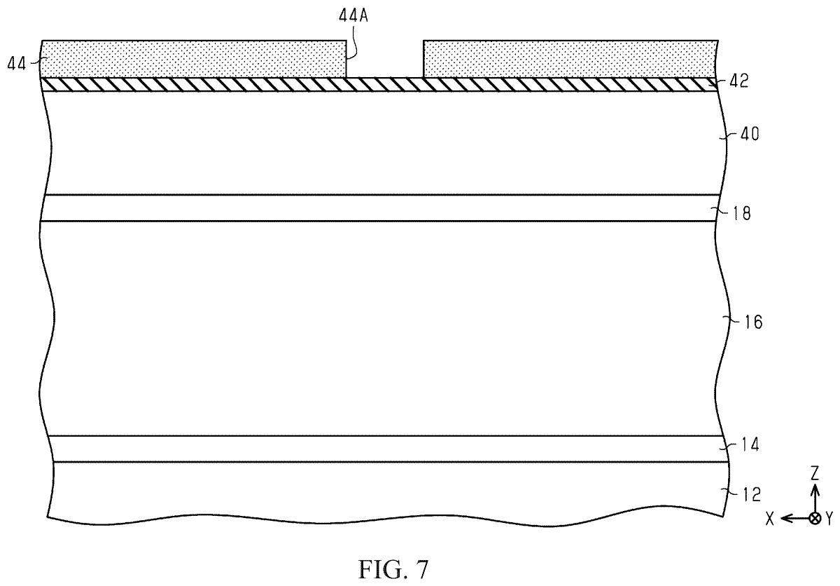

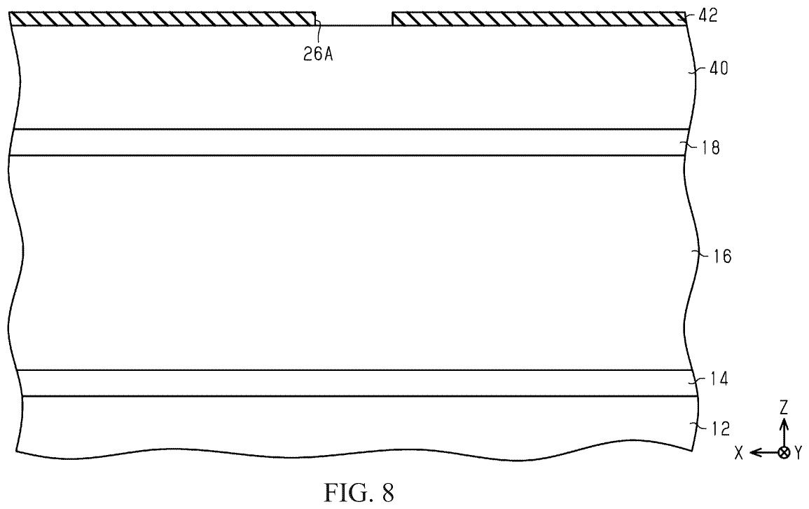

As shown in FIGS. 7 and 8, the method for manufacturing the nitride semiconductor device 10 includes forming an insulating film 42 having an opening 26A that exposes a portion of the nitride semiconductor layer 40.

As shown in FIG. 7, the insulating film 42 is formed on the nitride semiconductor layer 40 by, for example, Low-Pressure Chemical Vapor Deposition (LPCVD) method. The insulating film 42 is formed, for example, over the entire upper surface of the nitride semiconductor layer 40. The insulating film 42 is an insulating film constituting the first insulating film 26 (referring to FIG. 1), and may be formed of at least one of SiN, SiO₂, SiON, Al₂O₃, AlN and AlON, for example. In one example, the insulating film 42 is formed of Si₃N₄.

Next, a photoresist mask 44 is formed on the insulating film 42. The photoresist mask 44 includes an opening 44A that exposes a portion of the upper surface of the insulating film 42. The opening 44A is formed by selectively removing the photoresist mask 44 through photolithography and etching.

Next, as shown in FIG. 8, the insulating film 42 exposed in the opening 44A is removed by etching using the photoresist mask 44. Thereby, the opening 26A is formed in the insulating film 42. The etching may uses dry etching, for example.

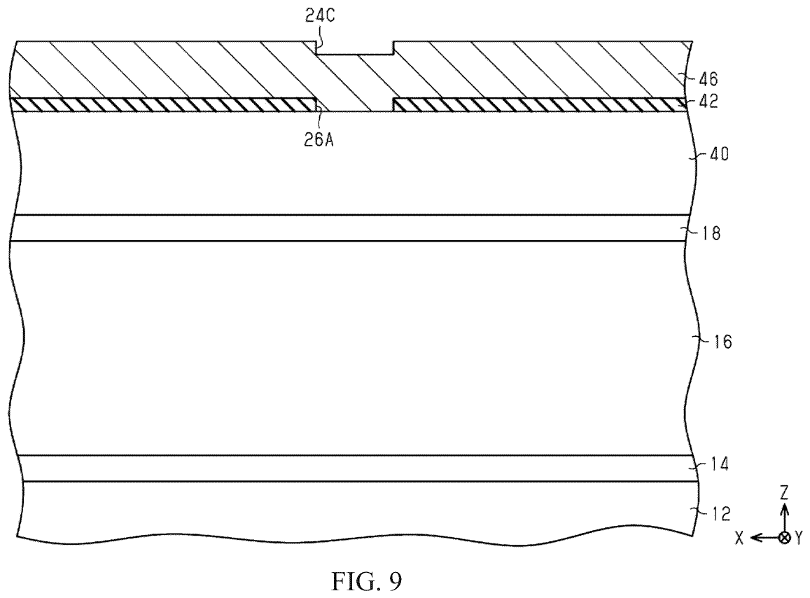

As shown in FIG. 9, the method for manufacturing the nitride semiconductor device 10 includes forming the electrode layer 46 connected to the nitride semiconductor layer 40 through the opening 26A. The electrode layer 46 is an electrode layer constituting the gate electrode 24 and is, for example, a TiN layer. The electrode layer 46 is formed by sputtering, for example. The electrode layer 46 fills the opening 26A and is formed over the entire upper surface of the insulating film 42. A recess 24C is formed in a portion of the upper end of the electrode layer 46 corresponding to the opening 26A.

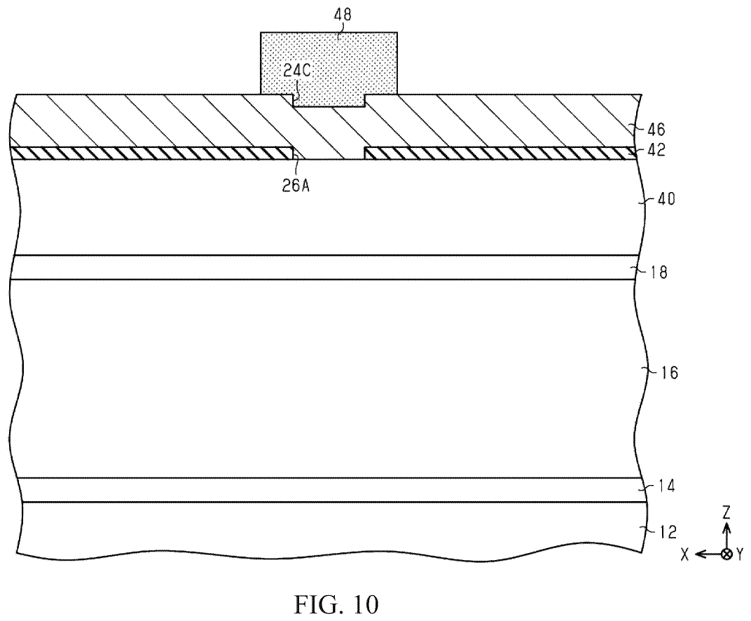

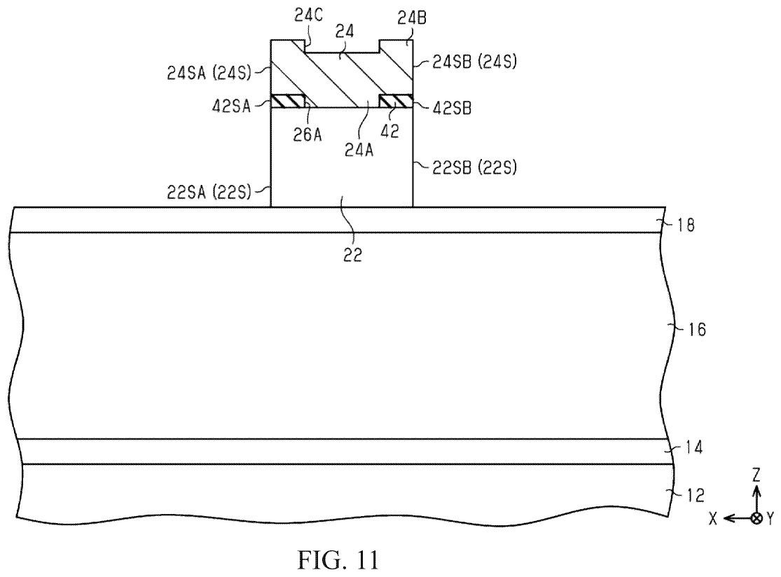

As shown in FIGS. 10 and 11, the method for manufacturing the nitride semiconductor device 10 includes etching the nitride semiconductor layer 40, the insulating film 42 and the electrode layer 46 to form the gate layer 22 on the electron supply layer 18, the first insulating film 26 having the opening 26A where a portion of the gate layer 22 is exposed, and the gate electrode 24 including the gate field plate portion 24B on the first insulating film 26 and the gate contact portion 24A that is in contact with the gate layer 22 through the opening 26A.

As shown in FIG. 10, a resist mask 48 is formed on the electrode layer 46. The resist mask 48 is formed on a portion of the upper surface of the electrode layer 46. More specifically, the resist mask 48 is formed on the recess 24C of the electrode layer 46 and its periphery.

Next, as shown in FIG. 11, the nitride semiconductor layer 40, the insulating film 42 and the electrode layer 46 are removed by etching using the resist mask 48. Thereby, the gate layer 22 is formed from the nitride semiconductor layer 40, and the gate electrode 24 is formed from the electrode layer 46. For etching, dry etching is used, for example.

The side surfaces 22SA and 22SB of the gate layer 22, the side surfaces 24SA and 24SB of the gate electrode 24 (the gate field plate portion 24B), and the side surfaces 42SA and 42SB of the insulating film 42 are flush with each other.

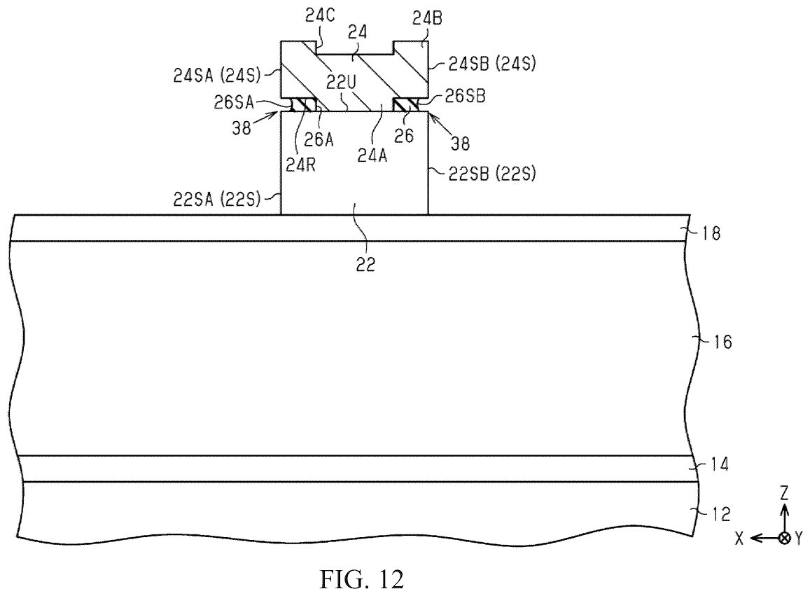

As shown in FIG. 12, the method for manufacturing the nitride semiconductor device 10 includes forming the first insulating film 26 comprising the side surfaces 26SA and 26SB located closer to the inside of the gate electrode 24 than the side surfaces 24SA and 24SB of the gate field plate portion 24B by removing a portion of the insulating film 42 exposed between the gate layer 22 and the gate electrode 24.

The first insulating film 26 is formed by removing the insulating film 42 in a specified direction (the X-axis direction). More specifically, the first insulating film 26 is formed by removing both end portions of the insulating film 42 in the X-axis direction including the side surfaces 42SA and 42SB. Thereby, the side surfaces 26SA and 26SB of the first insulating film 26 are located closer to the inner side of the gate layer 22 than the side surfaces 22SA and 22SB of the gate layer 22 and closer to the inner side of the gate electrode 24 than the side surfaces 24SA and 24SB of the gate field plate portion 24B.

Herein, the insulating film 42 is removed in a specified direction (the X-axis direction) by etching with less damage than dry etching. Etching that is less damaging than dry etching includes wet etching or chemical dry etching. In one example, the etching uses wet etching.

Since the first insulating film 26 is formed in this way, the recessed portion 38 is formed by the lower surface 24R of the gate field plate portion 24B, the side surface 26S of the first insulating film 26, and the upper surface 22U of the gate layer 22.

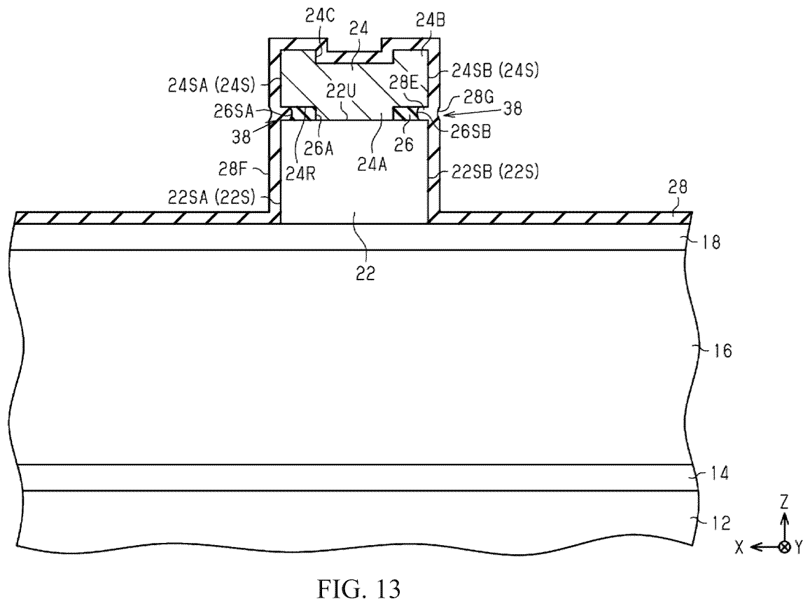

As shown in FIG. 13, the method for manufacturing the nitride semiconductor device 10 includes forming a second insulating film 28 covering at least the side surfaces 22SA, 22SB of the gate layer 22, the side surface 26SA, 26SB of the first insulating film 26, and the side surfaces 24SA, 24SB of the gate electrode 24 (the gate field plate portion 24B).

The second insulating film 28 is formed to cover the exposed upper surface of the electron supply layer 18 and the upper surface 24U of the gate electrode 24. The second insulating film 28 is formed by LPVCD, for example. The second insulating film 28 may be formed of at least one of SiN, SiO₂, SiON, Al₂O₃, AlN, and AlON. In one example, the second insulating film 28 is formed of Si₃N₄. That is, the second insulating film 28 is formed of the same material as the first insulating film 26. In addition, the second insulating film 28 may be formed of a different material from the first insulating film 26.

The second insulating film 28 forms an embedded portion 28E embedded in the recessed portion 38, and a recess 28G is formed on the outer surface 28F of the second insulating film 28. The recess 28G is formed in a portion of the outer surface 28F of the second insulating film 28 corresponding to the embedded portion 28E.

Next, the first opening 28A and the second opening 28B are formed to penetrate the second insulating film 28 and expose the electron supply layer 18. The first opening 28A and the second opening 28B are formed such that the gate layer 22 is located between the first opening 28A and the second opening 28B. The gate layer 22 may be located closer to the first opening 28A than the second opening 28B. The first opening 28A and the second opening 28B are formed by etching, for example.

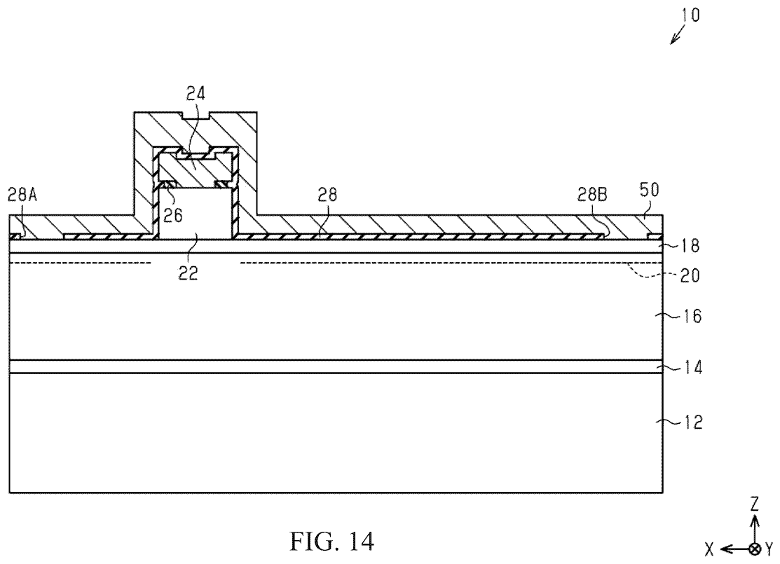

As shown in FIG. 14, the method for manufacturing the nitride semiconductor device 10 includes forming the source electrode 30 and the drain electrode 32 in contact with the electron supply layer 18 (both referring to FIG. 1).

In this step, a metal layer 50 is first formed on the second insulating film 28. The metal layer 50 is formed over the entire surface of the second insulating film 28. The metal layer 50 fills the first opening 28A and the second opening 28B, and is formed so as to be in contact with the electron supply layer 18 via the first opening 28A and the second opening 28B. In one example, the metal layer 50 may include at least one of a Ti layer, a TiN layer, an Al layer, an AlSiCu layer, and an AlCu layer.

Next, the metal layer 50 is selectively removed by photolithography and etching. Thereby, the source electrode 30 and the drain electrode 32 shown in FIG. 1 can be formed. That is, the source electrode 30 includes the source contact portion 30A in contact with the electron supply layer 18 and the source field plate portion 30B formed on the second insulating film 28. The source field plate portion 30B includes an embedded portion 30D, which is a portion embedded in the recess 28G of the second insulating film 28 (referring to FIG. 4). Through the above steps, the nitride semiconductor device 10 shown in FIG. 1 is manufactured.

### Effects

The operation of the nitride semiconductor device 10 of this embodiment will be described.

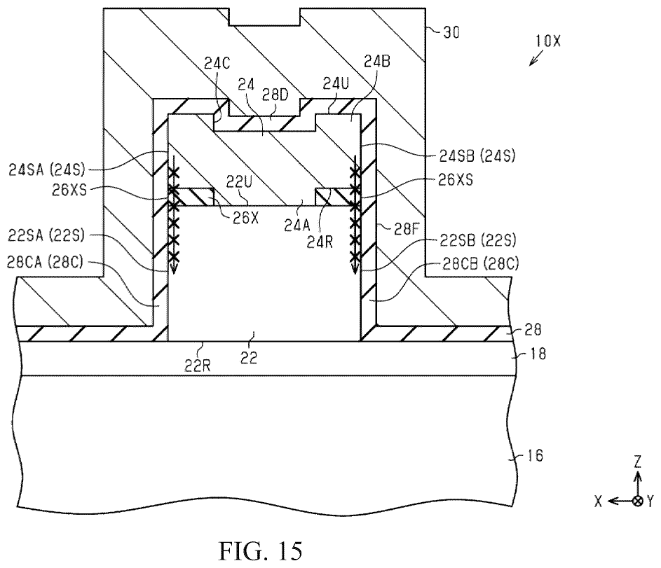

FIG. 15 is a cross-sectional view showing a schematic cross-sectional structure of a nitride semiconductor device 10X of a comparative example. Compared with the nitride semiconductor device 10 of this embodiment, the nitride semiconductor device 10X of the comparative example has a different structure of the first insulating film. Therefore, the first insulating film of the nitride semiconductor device 10X of the comparative example is referred to as “the first insulating film 26X” and its side surface is referred to as “side surface 26XS”. Since other structural elements are common to the structural elements of the nitride semiconductor device 10, they are designated by the same reference numerals.

As shown in FIG. 15, the side surface 26XS of the first insulating film 26X is flush with the side surface 22S of the gate layer 22 and the side surface 24S of the gate electrode 24 (the gate field plate portion 24B). That is, in the nitride semiconductor device 10X of the comparative example, the gate layer 22, the gate electrode 24 and the first insulating film 26X are formed by, for example, dry etching, and then the side surface 26XS of the first insulating film 26X is not removed. Therefore, as shown by the “x” marked in FIG. 15 , dry etching damage remains on each of the side surfaces 24S of the gate electrode 24, the side surfaces 26XS of the first insulating film 26X, and the side surfaces 22S of the gate layer 22.

Damage to the side surface 26XS of the first insulating film 26X may form a current path between the gate electrode 24 and the gate layer 22. Therefore, a gate leakage current path is generated along each of the side surface 24S of the gate electrode 24, the side surface 26XS of the first insulating film 26X, and the side surface 22S of the gate layer 22. Accordingly, when a voltage is applied to the gate electrode 24 of the nitride semiconductor device 10X of the comparative example, a gate leakage current flows through the path.

As shown in FIG. 3, in the nitride semiconductor device 10 of this embodiment, the side surface 26S of the first insulating film 26 is located closer to the inner side of the gate electrode 24 than the side surface 24S of the gate electrode 24 (the gate field plate portion 24B). That is, the side surfaces 42SA and 42SB of the insulating film 42 that remain damaged due to, for example, dry etching are removed by etching that is less damaged than the dry etching, thereby forming the first insulating film 26 including the side surfaces 26SA and 26SB. Therefore, no dry etching damage occurs on the side surfaces 26SA and 26SB of the first insulating film 26. This makes it difficult for current paths to occur on the side surfaces 26SA and 26SB of the first insulating film 26. In addition, as shown in FIG. 4, the recessed portion 38 made of the lower surface 24R of the gate field plate portion 24B, the side surfaces 26SA and 26SB of the first insulating film 26, and the upper surface 22U of the gate layer 22 is embedded with the second insulating film 28. Therefore, when a voltage is applied to the gate electrode 24 of the nitride semiconductor device 10, the gate leakage current is suppressed from flowing from the gate electrode 24 to the gate layer 22.

### Results

According to the nitride semiconductor device 10 of this embodiment, the following results can be obtained.

(1) The nitride semiconductor device 10 includes: the electron supply layer 18 made of the nitride semiconductor; the gate layer 22 made of the nitride semiconductor formed on the electron supply layer 18; the first insulating film 26 formed on the gate layer 22 and having the opening 26A that exposes the gate layer 22; the gate electrode 24 including the gate field plate portion 24B formed on the first insulating film 26 and the gate contact portion 24A in contact with the gate layer 22 through the opening 26A; and the source electrode 30 and the drain electrode 32 arranged on both sides in the predetermined direction with respect to the gate layer 22 and in contact with the electron supply layer 18. The first insulating film 26 includes the side surface 26S facing the same direction as the side surface 24S of the gate field plate portion 24B. The side surface 26S of the first insulating film 26 is located closer to the inner side of the gate electrode 24 than the side surface 24S of the gate field plate portion 24B. The nitride semiconductor device 10 includes the second insulating film 28 covering at least the side surfaces 22S, 24S, and 26S of each of the gate layer 22, the first insulating film 26 and the gate electrode 24. The second insulating film 28 includes a portion embedded in the recessed portion 38 formed by the lower surface 24R of the gate field plate portion 24B, the side surface 26S of the first insulating film 26 and the upper surface 22U of the gate layer 22.

According to the above configuration, since current paths are less likely to occur on the side surfaces 26SA and 26SB of the first insulating film 26, the current path from the side surface 24S of the gate electrode 24 to the side surface 22S of the gate layer 22 is blocked in the first insulating film 26, which can suppress the gate leakage current from flowing from the side surface 24S of the gate electrode 24 to the side surface 22S of the gate layer 22.

(2) The depth of the recessed portion 38 is smaller than the thickness of the first insulating film 26.

According to the above configuration, the second insulating film 28 is easily in contact with the side surface 26S of the first insulating film 26 constituting the bottom surface of the recessed portion 38. Therefore, the formation of a gap between the side surface 26S of the first insulating film 26 and the second insulating film 28 can be suppressed.

(3) The method for manufacturing the nitride semiconductor device 10 includes: forming the electron supply layer 18 made of nitride semiconductor; forming the nitride semiconductor layer 40 on the electron supply layer 18; forming the insulating film 42 on the nitride semiconductor layer 40 and having the opening 26A exposing a portion of the nitride semiconductor layer 40; forming the electrode layer 46 connected to the nitride semiconductor layer 40 through the opening 26A on the insulating film 42; forming the gate layer 22 on the electron supply layer 18 and the gate electrode 24 including the gate field plate portion 24B on the insulating film 42 and the gate contact portion 24A in contact with the gate layer 22 through the opening 26A by etching the nitride semiconductor layer 40, the insulating film 42 and the electrode layer 46; forming the first insulating film 26 including the side surface 26S located inside the gate electrode 24 from the side surface 24S of the gate field plate portion 24B by removing a portion of the insulating film 42 exposed between the gate layer 22 and the gate electrode 24; forming the second insulating film 28 including a portion embedded in a recessed portion 38 formed by the lower surface 24R of the gate field plate portion 24B, the side surface (26S) of the first insulating film 26, and the upper surface 22U of the gate layer 22, and covering at least each of the side surface of 22S of the gate layer 22, the side surface 26S of the first insulating film 26 and the side surface 24S of the gate electrode 24; and forming the source electrode 30 and the drain electrode 32 in contact with the electron supply layer 18 on both sides of the gate layer 22 in the predetermined direction (the X axis direction).

According to the above configuration, the first insulating film 26 including the side surfaces 26SA and 26SB is formed by removing a portion of the insulating film 42 exposed between the gate layer 22 and the gate electrode 24. As a result, dry etching damage is not present on the side surfaces 26SA and 26SB of the first insulating film 26. This makes it difficult for current paths to occur on the side surfaces 26SA and 26SB of the first insulating film 26. Therefore, the gate leakage current can be suppressed from flowing from the side surface 24S of the gate electrode 24 to the side surface 22S of the gate layer 22.

(4) In the method for manufacturing the nitride semiconductor device 10, the gate layer 22, the gate electrode 24 and the insulating film 42 are etched to form the side surfaces 22SA and 22SB of the gate layer 22, the side surfaces 24SA and 24SB of the plate portion 24B and side surfaces 42SA and 42SB of the insulating film 42 that are flush with each other. Then, the first insulating film 26 is formed by removing the insulating film 42 in a specified direction (the X-axis direction).

According to the above configuration, by forming the gate layer 22 and the gate electrode 24 in the same step, the manufacturing steps of the nitride semiconductor device 10 can be simplified. Furthermore, in a state where the side surfaces 22SA and 22SB of the gate layer 22, the side surfaces 24SA and 24SB of the gate field plate portion 24B, and the side surfaces 42SA and 42SB of the insulating film 42 are flush with each other, the insulating film 42 is removed in the specified direction (the X-axis direction), so the first insulating film 26 can be easily formed.

(5) Removing the insulating film 42 in the specified direction (the X-axis direction) by etching with less damage than dry etching.

According to the above configuration, damage to the side surface 26S of the first insulating film 26 formed by removing the insulating film 42 in a predetermined direction (the X-axis direction) is reduced. Therefore, the gate leakage current can be suppressed from flowing from the side surface 24S of the gate electrode 24 to the side surface 22S of the gate layer 22.

### MODIFIED EXAMPLES

The above-described embodiment can be modified and implemented as what follows.

The nitride semiconductor is not limited to GaN. In addition to GaN, representative examples of nitride semiconductors include aluminum nitride and indium nitride (InN). They can generally be expressed as AlₓIn_{y}Ga_{1-x-y}N (0≤x≤1, 0≤y≤1, 0≤x+y≤1).

The depth of the recessed portion 38 can be changed arbitrarily. In one example, the depth of the recessed portion 38 may be equal to or greater than the film thickness of the first insulating film 26. In one example, the depth of the recessed portion 38 may be equal to or greater than the film thickness of the second insulating film 28.

The shape of the recessed portion 38 can be modified arbitrarily. In one example, the recessed portion 38 may also be in a rectangular concave shape.

The shape of the side surfaces 26S (26SA, 26SB) of the first insulating film 26 can be changed arbitrarily. In one example, the portion of the curved side surface 26S of the first insulating film 26 located closest to the inner side of the first insulating film 26 may be closer to the upper surface 26U of the first insulating film 26 than the center of the first insulating film 26 in the thickness direction, or closer to the lower surface 26R of the first insulating film 26. The side surface 26S of the first insulating film 26 may be formed in a planar shape extending in the Z-axis direction. Furthermore, in another example, the side surface 26S of the first insulating film 26 may not be curved but may be formed in a flat shape along the Z-axis direction.

The position of the side surfaces 24S (24SA, 24SB) of the gate electrode 24 (the gate field plate portion 24B) in the X-axis direction can be changed arbitrarily. In one example, the side surface 24S of the gate electrode 24 may be located closer to the inner side of the gate layer 22 than the side surface 22S of the gate layer 22. In this case, the side surface 26S of the first insulating film 26 is also located closer to the inner side of the gate electrode 24 than the side surface 24S of the gate electrode 24.

The structure of the source electrode 30 can be changed arbitrarily. In one example, the source field plate portion 30B may be formed at a position spaced apart from the second insulating film 28 in the Z-axis direction. The source field plate portion 30B only needs to be formed so as to cover the gate electrode 24 in a top view. In another example, the source field plate portion 30B may be omitted from the source electrode 30.

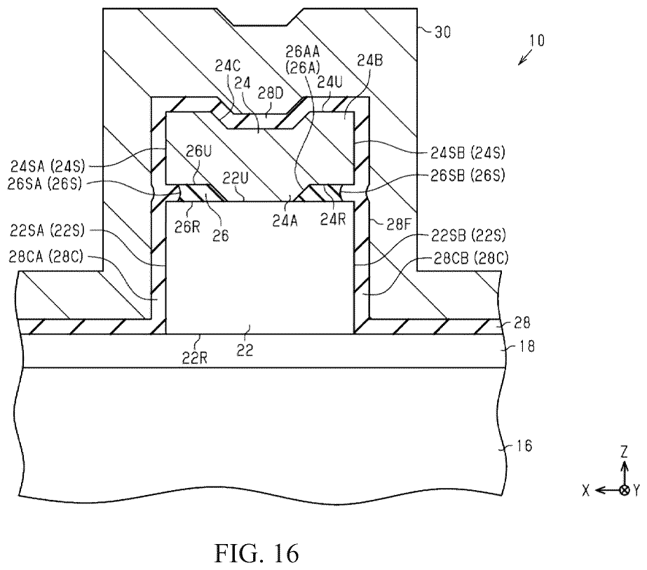

The shape of the opening 26A of the first insulating film 26 can be changed arbitrarily. In one example, as shown in FIG. 16, the openings 26A may be formed in a tapered shape that approaches each other as they approach the gate layer 22. Thereby, the gate contact portion 24A of the gate electrode 24 is formed into a trapezoidal shape that becomes gradually tapered toward the gate layer 22. In addition, the recess 24C of the gate electrode 24 corresponds to the shape of the opening 26A of the first insulating film 26 and includes side surfaces that approach each other as they approach the gate layer 22.

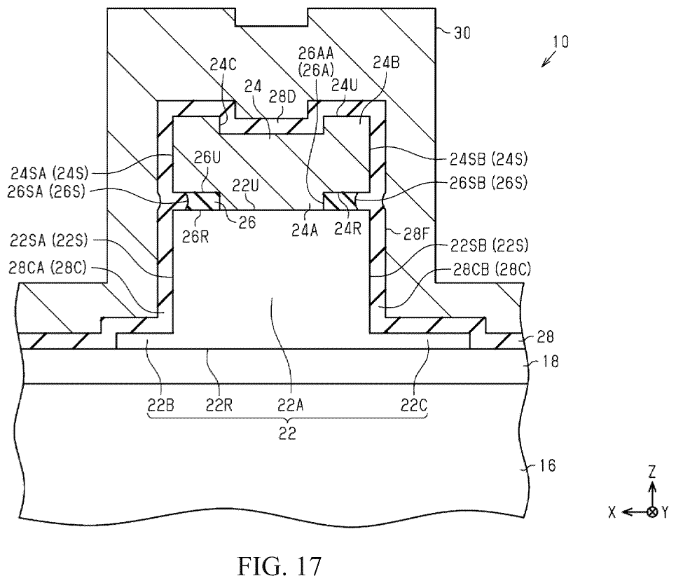

The structure of the gate layer 22 can be changed arbitrarily. In one example, as shown in FIG. 17, the gate layer 22 includes a gate layer body portion 22A, a source extension portion 22B extending from the gate layer body portion 22A toward the source electrode 30, and a drain extension portion 22C extending from the gate layer body portion 22A toward the drain electrode 32. The gate layer body portion 22A includes the upper surface 22U and the side surfaces 22SA and 22SB of the gate layer 22. The lower surface 22R of the gate layer 22 is composed of the lower surface of the gate layer body portion 22A, the lower surface of the source extension portion 22B, and the lower surface of the drain extension portion 22C. Therefore, the lower surface 22R of the gate layer 22 has a larger area than the upper surface 22U.

The gate layer body portion 22A is located between the source extension portion 22B and the drain extension portion 22C, and is integrally formed with the source extension portion 22B and the drain extension portion 22C. The gate layer body portion 22A corresponds to a relatively thick portion of the gate layer 22.

Both the source extension portion 22B and the drain extension portion 22C are thinner than the gate layer body portion 22A. Both the source extension portion 22B and the drain extension portion 22C may have a thickness that is less than half the thickness of the gate layer body portion 22A. The drain extension portion 22C may extend longer toward the outside of the gate layer body portion 22A than the source extension portion 22B in top view. That is, the drain extension portion 22C may have a larger size in the X-axis direction than the source extension portion 22B. The source extension portion 22B has a size of, for example, between about 0.2 μm and about 0.3 μm in the X-axis direction. On the other hand, the drain extension portion 22C has a size in the X-axis direction of, for example, between about 0.2 μm and about 0.6 μm.

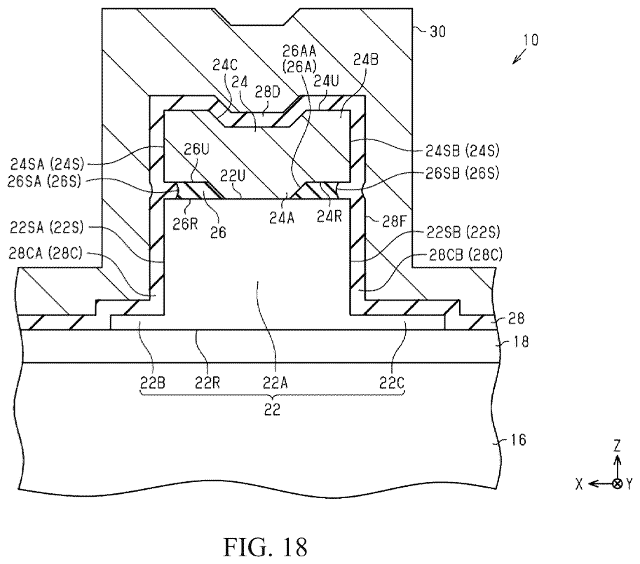

In addition, as shown in FIG. 18, in the gate layer 22 including the source extension portion 22B and the drain extension portion 22C, the opening 26A of the first insulating film 26 may be formed into tapered shapes that approach each other as they approach the gate layer 22.

In addition, in the modified examples shown in FIGS. 17 and 18, one of the source extension portion 22B and the drain extension portion 22C may be omitted from the gate layer 22. Since the gate layer 22 includes one of the source extension portion 22B and the drain extension portion 22C, local electric field concentration within the gate layer 22 can be suppressed.

One or more of the various examples described in this specification can be combined within the scope of not being technically inconsistent.

In this specification, “at least one of A and B” should be understood to mean “only A, only B, or both A and B”.

Terms such as “on” used in this disclosure include the meanings of “on” and “above” unless it is clear from the context that this is not the case. Therefore, expressions such as “the first element is installed on the second element” mean that in a certain embodiment, the first element may contact the second element and be directly arranged on the second element, and in other embodiments, the first element may not contact the second element is placed above the second element. In other words, terms such as “on” do not exclude the structure that forms other elements between the first element and the second element.

The Z-axis direction used in this disclosure does not have to be the vertical direction, nor does it need to be exactly the same as the vertical direction. Therefore, among the various structures of the present disclosure, the “upper” and “lower” in the Z-axis direction described in this specification are not limited to the “upper” and “lower” in the vertical direction. For example, the X-axis direction may be a vertical direction, or the Y-axis direction may be a vertical direction.

### Notes

Technical ideas that can be grasped from the above-described embodiments and modified examples are described below. In addition, the numerals of the constituent elements of the embodiment corresponding to the constituent elements described in each note are shown in parentheses. The numerals are shown as examples to assist understanding, and the constituent elements described in each note should not be limited to the constituent elements represented by the reference numerals.

### Note 1

A nitride semiconductor device (10), comprising:
an electron supply layer (18), made of nitride semiconductor;
a gate layer (22), made of nitride semiconductor formed on the electron supply layer (18);
a first insulating film (26), formed on the gate layer (22) and having an opening (26A) exposing the gate layer (22);
a gate electrode (24), including a gate field plate portion (24B) formed on the first insulating film (26) and a gate contact portion (24A) contacting the gate layer (22) through the opening (26A); and
a source electrode (30) and a drain electrode (32) arranged on both sides of the gate layer (22) in a predetermined direction (X-axis direction) and in contact with the electron supply layer (18);
the first insulating film (26) includes a side surface (26S) facing same direction as a side surface (24S) of the gate field plate portion (24B);
the side surface (26S) of the first insulating film (26) is located further inside the gate electrode (24) than the side surface (24S) of the gate field plate portion (24B); and the nitride semiconductor device (10) includes:
a second insulating film (28) covering at least each of a side surface (22S) of the gate layer(22), a side surface (26S) of the first insulating film (26) and a side surface (24S) of the gate electrode (24);
the second insulating film (28) includes a portion embedded in a recessed portion (38) formed by a lower surface (24R) of the gate field plate portion (24B), the side surface (26S) of the first insulating film (26) and an upper surface (22U) of the gate layer (22).

### Note 2

The nitride semiconductor device according to note 1, wherein a depth of the recessed portion (38) is less than a thickness of the first insulating film (26).

### Note 3

The nitride semiconductor according to note 1 or 2, wherein the recessed portion (38) is formed in a curved shape.

### Note 4

The nitride semiconductor device according to any one of notees 1 to 3, wherein the opening (26A) is formed in a tapered shape approaching each other when getting close to the gate layer (22).

### Note 5

The nitride semiconductor device according to any one of notees 1 to 4, wherein the side surface (26A) of the first insulating film (26) is located closer to an inner side of the gate layer (22) than the side surface (22S) of the gate layer (22).

### Note 6

The nitride semiconductor device according to any one of notees 1 to 5, wherein the side surface (22S) of the gate layer (22) and the side surface (24S) of the gate electrode (24) are at same position as each other in the predetermined direction (X-axis direction).

### Note 7

The nitride semiconductor device according to any one of notees 1 to 6, wherein the first insulating film (26) includes at least one of SiN, SiO₂, SiON, Al₂O₃, AlN, and AlON.

### Note 8

The nitride semiconductor device according to any one of notees 1 to 7, wherein the second insulating film (28) includes at least one of SiN, SiO₂, SiON, Al₂O₃, AlN, and AlON.

### Note 9

The nitride semiconductor device according to any one of notees 1 to 8, wherein the first insulating film (26) and the second insulating film (28) are formed of same material.

### Note 10

The nitride semiconductor device according to any one of notees 1 to 9, wherein an outer surface (28F) of the second insulating film (28) includes a recess (28G) that is recessed by being embedded in the recessed portion (38).

### Note 11

The nitride semiconductor device according to notees 10, wherein the source electrode (30) includes:
a source contact portion (30A), in contact with the electron supply layer (18); and
a source field plate portion (30B), formed on the second insulating film (28), wherein the source field plate portion (30B) is embedded in the recess (28G) of the second insulating film (28).

### Note 12

The nitride semiconductor device according to any one of notees 1 to 11, wherein the gate layer (22) includes:
a gate layer body portion (22A);
a source extension portion (22B), extending from the gate layer body portion (22A) toward the source electrode (30); and
a drain extension portion (22C), extending from the gate layer body portion (22A) toward the drain electrode (32).

### Note 13

The nitride semiconductor device according to any one of notees 1 to 12, wherein the electron supply layer (18) comprises AlₓGa₁₋ₓN, and 0.1<x<0.3.

### Note 14

The nitride semiconductor device according to any one of notees 1 to 13, wherein the upper surface (22U) of the gate layer (22) forms a Schottky junction with the gate electrode (24).

### Note 15

A method for manufacturing a nitride semiconductor device (10), comprising:
forming an electron supply layer (18) made of nitride semiconductor;
forming a nitride semiconductor layer (40) on the electron supply layer (18);
forming an insulating film (42) on the nitride semiconductor layer (40) and having an opening (26A) exposing a portion of the nitride semiconductor layer (40);
forming an electrode layer (46) connected to the nitride semiconductor layer (40) through the opening (26A) on the insulating film (42);
forming a gate layer (22) and a gate electrode (24) on the electron supply layer (18) by etching the nitride semiconductor layer (40), the insulating film (42) and the electrode layer (46), and the gate electrode (24) including a gate field plate portion (24B) on the insulating film (42) and a gate contact portion (24A) in contact with the gate layer (22) through the opening (26A);
forming a first insulating film (26) including a side surface located inside the gate electrode (24) from a side surface (24S) of the gate field plate portion (24B) by removing a portion of the insulating film (42) exposed between the gate layer (22) and the gate electrode (24);
forming a second insulating film (28) including:
a portion embedded in a recessed portion (38) formed by a lower surface (24R) of the gate field plate portion (24B);
the side surface (26S) of the first insulating film (26); and
an upper surface (22U) of the gate layer (22), wherein the second insulating film (28) covers at least each of a side surface of (22S) the gate layer (22), a side surface (24S) of the gate electrode (24) and the side surface of the first insulating film (42); and
forming a source electrode (30) and a drain electrode (32) in contact with the electron supply layer (18) on both sides of the gate layer (22) in a predetermined direction (X axis direction).

### Note 16

The method for manufacturing a nitride semiconductor device according to note 15, wherein
the side surfaces (22SA, 22SB, 24SA, 24SB, 42SA, 42SB) of the gate layer (22), the gate field plate portion (24B) and the insulating film (42) are formed to be planar with each other by etching the gate layer (22), the gate electrode (24) and the insulating film (42), and
the first insulating film (26) is formed by removing the insulating film (42) in the predetermined direction (the X axis direction).

### Note 17

The method for manufacturing a nitride semiconductor device according to note 15 or 16, wherein
an outer surface (28F) of the second insulating film (28) includes a recess (28G) that is recessed by being embedded in the recessed portion (38), and
the source electrode (30) includes:
a source contact portion (30A), in contact with the electron supply layer (18); and
a source field plate portion (30B), formed on the second insulating film (28), wherein the source field plate portion (30B) includes a portion embedded in the recess (28G) of the second insulating film (28).

### Note 18

The method for manufacturing a nitride semiconductor device according to notees 15 to 17, wherein
the etching for forming the gate layer (22), the gate electrode (24) and the insulating film (42) is a dry etching, and
the insulating film (42) is removed in the predetermined direction (X axis direction) by an etching that causes less damage than the dry etching.

### Note 19

The method for manufacturing a nitride semiconductor device according to note 18, wherein the etching that causes less damage than the dry etching includes a wet etching or a chemical dry etching.

The above description is only an example. Those skilled in the art can realize that in addition to the constituent elements and methods (manufacturing processes) listed for the purpose of explaining the technology of the present disclosure, more conceivable combinations and substitutions are possible. The disclosure is intended to include all substitutions, changes, and modifications included within the scope of the disclosure including the claims.

1. A nitride semiconductor device, comprising:
an electron supply layer, made of nitride semiconductor;
a gate layer, made of nitride semiconductor and formed on the electron supply layer;
a first insulating film, formed on the gate layer and having an opening exposing the gate layer;
a gate electrode, including:
a gate field plate portion, formed on the first insulating film; and
a gate contact portion, contacting the gate layer through the opening; and
a source electrode and a drain electrode, arranged on both sides of the gate layer in a predetermined direction and in contact with the electron supply layer, wherein
the first insulating film includes a side surface facing same direction as a side surface of the gate field plate portion,
the side surface of the first insulating film is located further inside the gate electrode than the side surface of the gate field plate portion,
a second insulating film covering at least each of a side surface of the gate layer, a side surface of the gate electrode and the side surface of the first insulating film, and
the second insulating film includes a portion embedded in a recessed portion formed by a lower surface of the gate field plate portion, the side surface of the first insulating film and an upper surface of the gate layer.

2. The nitride semiconductor device of claim 1, wherein a depth of the recessed portion is less than a thickness of the first insulating film.

3. The nitride semiconductor device of claim 1, wherein the recessed portion is formed in a curved shape.

4. The nitride semiconductor device of claim 1, wherein the opening is formed in a tapered shape approaching each other when getting close to the gate layer.

5. The nitride semiconductor device of claim 1, wherein the side surface of the first insulating film is located further inside the gate layer than the side surface of the gate layer.

6. The nitride semiconductor device of claim 1, wherein the side surface of the gate layer and the side surface of the gate electrode are at same position as each other in the predetermined direction.

7. The nitride semiconductor device of claim 1, wherein the first insulating film includes at least one of SiN, SiO₂, SiON, Al₂O₃, AlN, and AlON.

8. The nitride semiconductor device of claim 1, wherein the second insulating film includes at least one of SiN, SiO₂, SiON, Al₂O₃, AlN, and AlON.

9. The nitride semiconductor device of claim 1, wherein the first insulating film and the second insulating film are formed of same material.

10. The nitride semiconductor device of claim 1, wherein an outer surface of the second insulating film includes a recess 28G that is recessed by being embedded in the recessed portion 38.

11. The nitride semiconductor device of claim 10, wherein the source electrode includes:
a source contact portion, in contact with the electron supply layer; and
a source field plate portion, formed on the second insulating film, wherein the source field plate portion is embedded in the recess 28G of the second insulating film.

12. The nitride semiconductor device of claim 1, wherein the gate layer includes:
a gate layer body portion;
a source extension portion, extending from the gate layer body portion toward the source electrode; and
a drain extension portion, extending from the gate layer body portion toward the drain electrode.

13. The nitride semiconductor device of claim 1, wherein the electron supply layer comprises AlₓGa₁₋ₓN, and 0.1<x<0.3.

14. The nitride semiconductor device of claim 1, wherein the upper surface of the gate layer forms a Schottky junction with the gate electrode.

15. The nitride semiconductor device of claim 2, wherein the upper surface of the gate layer forms a Schottky junction with the gate electrode.

16. A method for manufacturing a nitride semiconductor device, comprising:
forming an electron supply layer made of nitride semiconductor;
forming a nitride semiconductor layer on the electron supply layer;
forming an insulating film on the nitride semiconductor layer and having an opening exposing a portion of the nitride semiconductor layer;
forming an electrode layer connected to the nitride semiconductor layer through the opening on the insulating film;
forming a gate electrode including a gate layer on the electron supply layer, a gate field plate portion on the insulating film, and a gate contact portion in contact with the gate layer through the opening by etching the nitride semiconductor layer, the insulating film and the electrode layer;
forming a first insulating film including a side surface located inside the gate electrode from a side surface of the gate field plate portion by removing a portion of the insulating film exposed between the gate layer and the gate electrode;
forming a second insulating film including:
a portion embedded in a recessed portion formed by a lower surface of the gate field plate portion;
the side surface of the first insulating film; and
an upper surface of the gate layer, wherein the second insulating film covers at least each of a side surface of the gate layer, a side surface of the gate electrode and the side surface of the first insulating film; and
forming a source electrode and a drain electrode in contact with the electron supply layer on both sides of the gate layer in a predetermined direction.

17. A method of claim 16, wherein
the side surfaces of the gate layer, the gate field plate portion and the insulating film are formed to be planar with each other by etching the gate layer, the gate electrode and the insulating film, and
the first insulating film is formed by removing the insulating film in the predetermined direction.

18. A method of claim 16, wherein
an outer surface of the second insulating film includes a recess that is recessed by being embedded in the recessed portion, and
the source electrode includes:
a source contact portion, in contact with the electron supply layer; and
a source field plate portion, formed on the second insulating film, wherein the source field plate portion includes a portion embedded in the recess of the second insulating film.

19. A method of claim 16, wherein
the etching for forming the gate layer, the gate electrode and the insulating film is a dry etching, and
the insulating film is removed in the predetermined direction by an etching that causes less damage than the dry etching.

20. A method of claim 19, wherein the etching that causes less damage than the dry etching includes a wet etching or a chemical dry etching.
